(19) United States
(12) Patent Application Publication
(10) Pub. No.: US 2026/0223310 A1
(43) Pub. Date: Jul. 30, 2026

(54) WIRING MODULE

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Daiji YOSHITO, Osaka (JP); Hideo TAKAHASHI, Osaka (JP)

(21) Appl. No.: 19/141,320

(22) PCT Filed: Dec. 7, 2023
(86) PCT No.: PCT/JP2023/043803

§ 371 Date: Jun. 20, 2025

(30) Foreign Application Priority Data
Dec. 22, 2022 (JP) 2022-205220

(51) Int. Cl. H05K 7/14

(52) U.S. Cl. CPC H05K 7/1427

(57) ABSTRACT

A wiring module is to be attached to a plurality of power storage elements and includes a plurality of circuit boards, a plurality of wires and a protector for holding the plurality of circuit boards and the plurality of wires. The wire is connected to the circuit board. At least some of the plurality of wires are integrally bundled to constitute a main line. The protector includes a placing surface, on which the circuit boards are placed, a wire accommodating portion for accommodating the plurality of wires and a main line accommodating portion overlapped on the wire accommodating portion in a first direction orthogonal to the placing surface for accommodating at least a part of the main line. The plurality of wires include at least one overlapping wire to be disposed to overlap the main line when viewed from the first direction.

### DESCRIPTION

### Technical Field

The present disclosure relates to a wiring module.

### Background

In a high-voltage battery pack used in an electric vehicle, a hybrid vehicle or the like, a multitude of battery cells are normally stacked and electrically connected in series or in parallel by a wiring module. A wiring module described in Japanese Patent Laid-Open Publication No. 2018-085201 (Patent Document 1 below) is conventionally known as such a wiring module. This wiring module is provided with busbar terminals for connecting power storage elements to each other, detection wires to be connected to the busbar terminals and a female connector to be connected to the detection wires.

### PRIOR ART DOCUMENT

### Patent Document

Patent Document 1: JP. 2018-085201 A

### SUMMARY OF THE INVENTION

### Problems to Be Solved

In Patent Document 1, a plurality of the detection wires are collected by a tube-like member on the female connector side. In the above configuration, for example, if wires different from the detection wires are provided, the detection wires collected by the tube-like member and the individual wires are possibly arranged in the same routing region in an insulating protector. In such a case, friction is possibly generated between the individual wires and the tube-like member due to vibration in a vehicle in which the wiring module is disposed. Further, in connecting the female connector to a male connector on a device side, friction is possibly generated between the individual wires and the tube-like member also by displacements of the detection wires in a routing direction. If friction is generated between the individual wires and the tube-like member, stresses act on connected parts of the individual wires and other members such as the busbar terminals and circuit boards, and these connected parts may be damaged.

### Means to Solve the Problem

The present disclosure is directed to a wiring module to be attached to a plurality of power storage elements, the wiring module being provided with a plurality of circuit boards, a plurality of wires and a protector for holding the plurality of circuit boards and the plurality of wires, the wire being connected to the circuit board, at least some of the plurality of wires being integrally bundled to constitute a main line, the protector including a placing surface, the circuit boards being placed on the placing surface, a wire accommodating portion for accommodating the plurality of wires and a main line accommodating portion overlapped on the wire accommodating portion in a first direction orthogonal to the placing surface for accommodating at least a part of the main line, the plurality of wires including at least one overlapping wire to be disposed to overlap the main line when viewed from the first direction, and the main line accommodating portion separating the main line and the at least one overlapping wire.

### Effect of the Invention

According to the present disclosure, it is possible to provide a wiring module capable of suppressing the damage of a connected part of a wire and a circuit board.

### BRIEF DESCRIPTION OF THE DRAWINGS

FIG. 1 is a schematic diagram showing a vehicle installed with a power storage module according to an embodiment.

FIG. 2 is a plan view of the power storage module when a main line is in a contracted state.

FIG. 3 is a plan view of the power storage module when the main line is in an elongated state.

FIG. 4 is a plan view of the power storage module with a cover removed when the main line is in the contracted state.

FIG. 5 is a plan view of the power storage module with the cover removed when the main line is in the elongated state.

FIG. 6 is a section along A-A of FIG. 2.

FIG. 7 is a perspective view of the cover.

### DETAILED DESCRIPTION TO EXECUTE THE INVENTION

### Description of Embodiments of Present Disclosure

First, embodiments of the present disclosure are listed and described.

(1) The wiring module of the present disclosure is to be attached to a plurality of power storage elements, and provided with a plurality of circuit boards, a plurality of wires and a protector for holding the plurality of circuit boards and the plurality of wires, the wire being connected to the circuit board, at least some of the plurality of wires being integrally bundled to constitute a main line, the protector including a placing surface, the circuit boards being placed on the placing surface, a wire accommodating portion for accommodating the plurality of wires and a main line accommodating portion overlapped on the wire accommodating portion in a first direction orthogonal to the placing surface for accommodating at least a part of the main line, the plurality of wires including at least one overlapping wire to be disposed to overlap the main line when viewed from the first direction, and the main line accommodating portion separating the main line and the at least one overlapping wire.

According to this configuration, since the main line accommodating portion separates the main line and the overlapping wire, friction is not generated between the main line and the overlapping wire. Therefore, the damage of a connected part of the overlapping wire and the circuit board can be suppressed.

Further, since the overlapping wire is disposed to overlap the main line when viewed from the first direction, a routing region for the overlapping wire and the main line can be reduced in a direction parallel to the placing surface. Therefore, the wiring module can be reduced in size.

(2) Preferably, the protector includes a protector body and a cover to be overlapped on the protector body in the first direction, the protector body includes the placing surface and the wire accommodating portion, and the cover includes a ceiling plate portion facing the placing surface in the first direction and the main line accommodating portion recessed from the ceiling plate portion.

According to this configuration, the main line accommodating portion can be simply configured. Further, the placing surface can be covered by the ceiling plate portion.

### Details of Embodiment of Present Disclosure

Hereinafter, an embodiment of the present disclosure is described. The present disclosure is not limited to these illustrations, but is represented by claims and intended to include all changes in the scope of claims and in the meaning and scope of equivalents.

### Embodiment

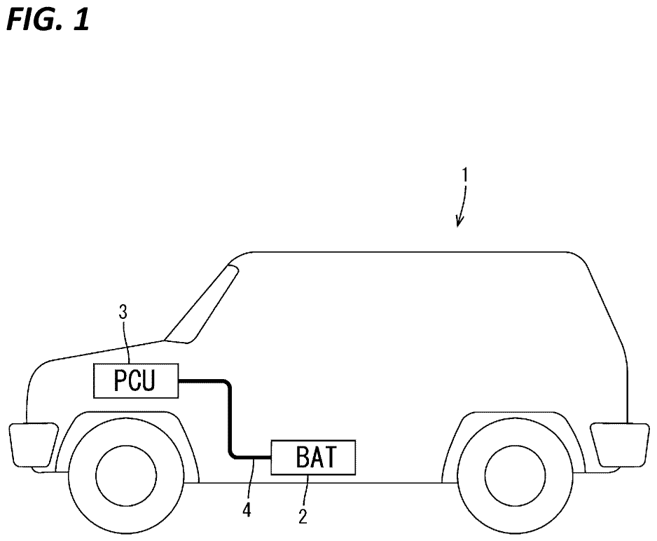

An embodiment of the present disclosure is described with reference to FIGS. 1 to 7. A power storage module 10 provided with a wiring module 20 of this embodiment is, for example, applied to a power storage pack 2 installed in a vehicle 1 as shown in FIG. 1. The power storage pack 2 is installed in the vehicle 1 such as an electric vehicle or a hybrid vehicle and used as a drive source of the vehicle 1. In the following description, for a plurality of identical members, only some members may be denoted by a reference sign and the other members may not be denoted by the reference sign.

As shown in FIG. 1, the power storage pack 2 is disposed near a center of the vehicle 1. APCU (Power Control Unit) 3 is disposed in a front part of the vehicle 1. The power storage pack 2 and the PCU 3 are connected by a wiring harness 4. The power storage pack 2 and the wiring harness 4 are connected by an unillustrated connector. The power storage pack 2 includes the power storage module 10 provided with a plurality of power storage elements 11. In the following description, a direction indicated by an arrow Z is referred to as an upward direction, a direction indicated by an arrow X is referred to as a forward direction and a direction indicated by an arrow Y is referred to as a leftward direction except in FIG. 1.

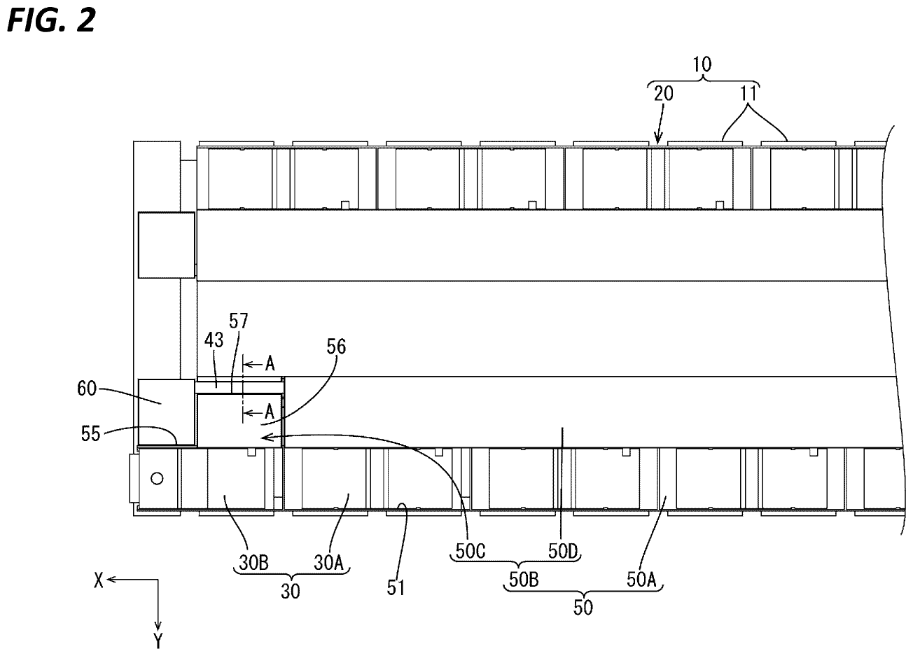

As shown in FIG. 2, the power storage module 10 is provided with a plurality of power storage elements 11 arranged in a row and the wiring module 20 to be mounted on the upper surfaces of the plurality of power storage elements 11. The power storage element 11 has a flat rectangular parallelepiped shape and a power storage component is accommodated inside. Although not shown, the power storage element 11 includes a pair of electrode terminals at a position near a right end part and a position near a left end part on the upper surface. One of the pair of electrode terminals is a positive electrode, and the other is a negative electrode.

### Wiring Module

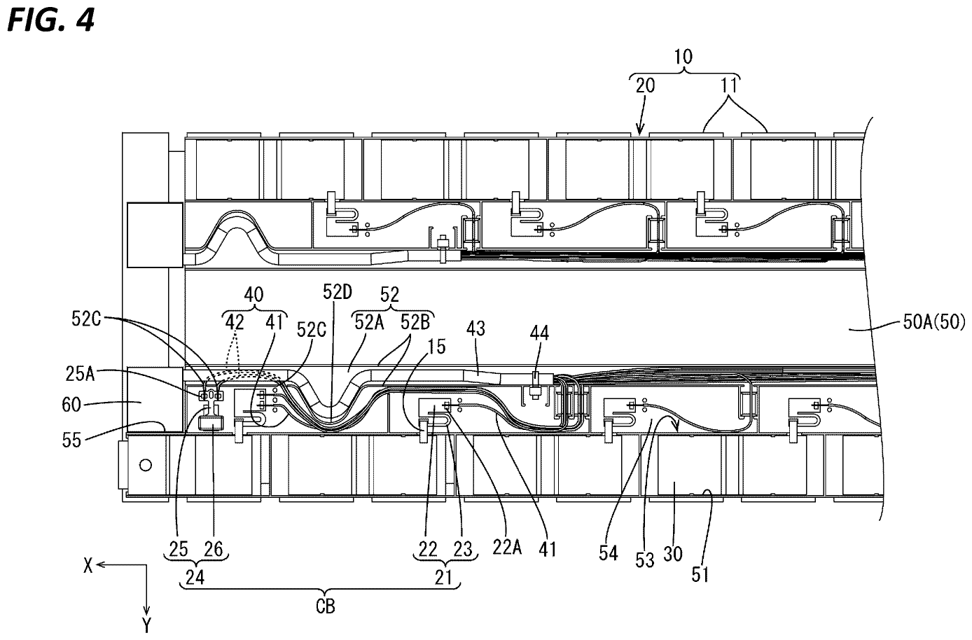

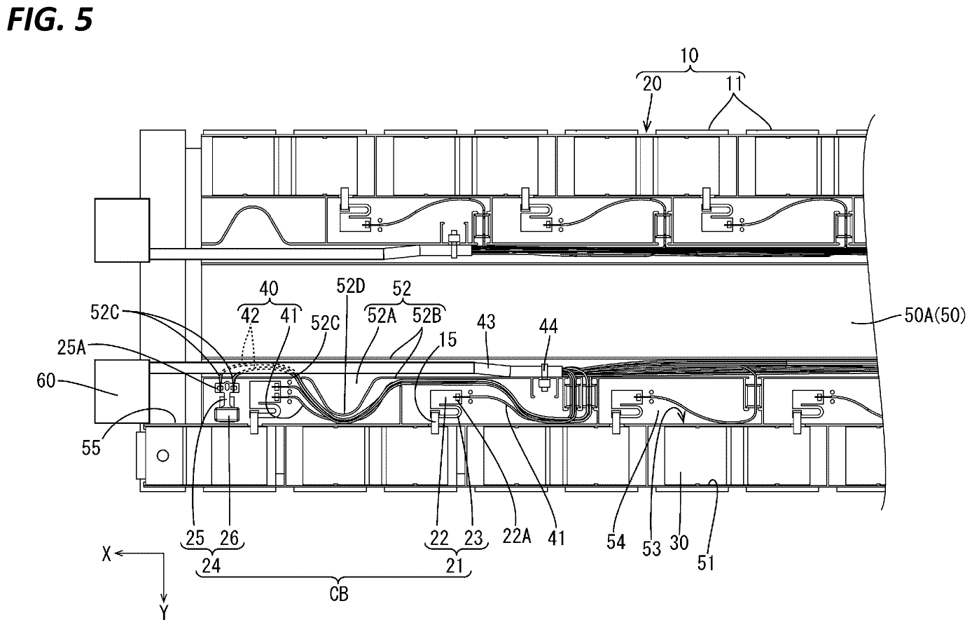

As shown in FIGS. 4 and 5, the wiring module 20 is provided with busbars 30 to be connected to the electrode terminals of the power storage elements 11, a plurality of circuit boards CB, a plurality of wires 40 and a protector 50 for holding the busbars 30, the plurality of circuit boards CB and the of wires 40. At least one wire 40 is connected to each of the plurality of circuit boards CB.

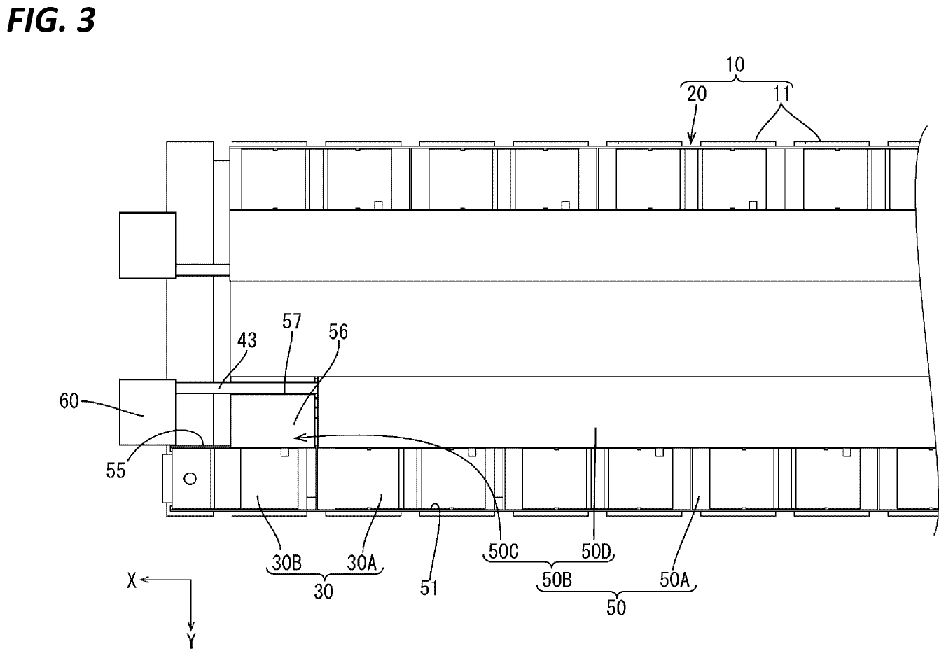

The busbars 30 are constituted by metal plate members and have a rectangular shape in a plan view. As shown in FIGS. 2 and 3, the busbars 30 include connection busbars 30A for connecting the electrode terminals adjacent in a stacking direction (front-rear direction) of the plurality of power storage elements 11 and output busbars 30B to be connected to the electrode terminals of the power storage element 11 disposed in an end part in the stacking direction. The output busbar 30B connects total positive electrodes or total negative electrodes of the plurality of power storage elements 11 and an external device. The busbars 30 and the electrode terminals are connected by welding or the like. The busbars 30 are accommodated in busbar accommodating portions 51 of the protector 50 to be described later.

### Circuit Boards

As shown in FIGS. 4 and 5, the plurality of circuit boards CB according to this embodiment include a plurality of first circuit boards 21 and at least one second circuit board 24. The first circuit board 21 is a flexible board in this embodiment and configured by forming an electrically conductive path on a surface of a flexible insulating sheet by a printed wiring technique. The first circuit board 21 is provided with a board body 22 and an extending portion 23 extending from the board body 22. The board body 22 has a substantially rectangular shape in a plan view. The board body 22 is fixed to a placing surface 54 of the protector 50 to be described later. Although not described in detail, the board body 22 is, for example, provided with an insertion hole, and a projection projecting from the placing surface 54 is inserted into this insertion hole. The board body 22 is provided with a wire land 22A disposed on one end of the electrically conductive path. The wire land 22A is connected to a voltage detection line 41 to be described later by soldering or the like.

The extending portion 23 is U-shaped in a plan view and configured to be stretchable. By providing the extending portion 23, an end part (tip part) of the extending portion 23 on a side opposite to the board body 22 is allowed to be displaced by a predetermined dimension with respect to the board body 22. The other end (not shown) of the electrically conductive path is disposed on the tip part of the extending portion 23. The other end of the electrically conductive path is electrically connected to the busbar 30 via a small metal piece 15. Although not shown, a fuse or the like may be provided in the electrically conductive path of the first circuit board 21.

The second circuit board 24 is, for example, a flexible board and configured by forming electrically conductive paths on a surface of a flexible insulating sheet by the printed wiring technique. The second circuit board 24 is provided with a board body 25 and a temperature measuring element 26 mounted on a land of the board body 25. The board body 25 is substantially T-shaped in a plan view. The board body 25 is fixed to the plating surface 54 of the protector 50 to be described later, similarly to the board body 22 of the first circuit board 21. The board body 25 is provided with wire lands 25A disposed on one ends of the electrically conductive paths. The wire land 25A is connected to temperature detection lines 42 to be described later by soldering or the like. A thermistor, a platinum temperature measuring resistor or the like can be, for example, used as the temperature measuring element 26.

### Wires

The plurality of wires 40 of this embodiment include a plurality of the voltage detection lines 41 and a plurality of the temperature detection lines 42. The voltage detection line 41 is connected to the first circuit board 21. The temperature detection lines 42 are connected to the second circuit board 24. Since the voltage detection lines 41 and the temperature detection lines 42 are similarly configured, the voltage detection lines 41 are described as representatives for the overlapping configuration. The voltage detection line 41 has a known configuration by covering a core wire formed by twisting a plurality of strands by an insulation coating.

### Main Line

The plurality of wires 40 constitute a main line 43 by being integrally bundled. Specifically, the plurality of wires 40 can be bundled by being taped or accommodated in a corrugated tube. The main line 43 is accommodated into a wire accommodating portion 52 and a main line accommodating portion 57 (see FIG. 2) of the protector 50 to be described later. One end part (front end part) of the main line 43 is connected to a connector 60 to be described later. The plurality of wires 40 are led out from the other end part (rear end part) of the main line 43. The other end part of the main line 43 is fixed to the protector 50 by a fixing portion 44. The fixing portion 44 is, for example, constituted by a zip tie and fixed to the protector 50 by being wound on the main line 43.

### Overlapping Wires

The plurality of wires 40 include at least one overlapping wire to be disposed to overlap the main line 43 when viewed from a vertical direction. The overlapping wires according to this embodiment are, for example, two temperature detection lines 42 disposed in a front end part of the wiring module 20. Further, in this embodiment, the overlapping wires are also included in the main line 43.

The plurality of wires 40 are connected to the connector 60 on an end part on a side opposite to the circuit boards CB. This connector 60 is connected to a mating connector provided in an external ECU (Electronic Control Unit) or the like. The ECU is mounted with a microcomputer, elements and the like, and has a known configuration provided with functions of detecting a voltage, a current, a temperature and the like of each power storage element 11 and controlling the charge/discharge of each power storage element 11.

As shown in FIGS. 2 and 3, a connector accommodating portion 55 for accommodating the connector 60 is provided in a front end part of the protector 50. The connector accommodating portion 55 is a space formed by cutting a part of the protector 50. The front end of the connector accommodating portion 55 is aligned with the front end of the protector 50. With the connector 60 accommodated in the connector accommodating portion 55, the front end of the connector 60 does not protrude forward from the front end of the protector 50.

### Protector

The protector 50 is made of insulating synthetic resin. The protector 50 is provided with a protector body 50A and a cover 50B for covering the protector body 50A from above.

### Protector Body

The protector body 50A is in the form of a tray. As shown in FIG. 4, the protector body 50A is provided with the busbar accommodating portions 51 for accommodating the busbars 30, the wire accommodating portions 52 for accommodating the plurality of wires 40 and intermediate routing portions 53 disposed between the busbar accommodating portions 51 and the wire accommodating portions 52. The busbar accommodating portions 52 are provided in both end parts in a lateral direction of the protector body 50A. The busbar accommodating portions 51 are frame-shaped, and arranged side by side in the front-rear direction. The intermediate routing portion 53 has the placing surface 54, on which the circuit boards CB are placed. The placing surface 54 is a surface orthogonal to the vertical direction (an example of a first direction).

### Wire Accommodating Portions

Two wire accommodating portions 52 are provided at positions near a lateral central part of the protector body 50A. The wire accommodating portion 52 is groove-like and extends in the front-rear direction. The wire accommodating portion 52 includes a bottom wall 52A and a pair of side walls 52B rising upward from both left and right end edges of the bottom wall 52A. The side wall 52B of the wire accommodating portion 52 on the side of the intermediate routing portion 53 is formed with a plurality of cut portions 52C. The plurality of wires 40 are accommodated in the wire accommodating portion 52. The wires 40 are insertable between the intermediate routing portion 53 and the wire accommodating portion 52 via the cut portions 52C.

A part of the side wall 52B on the side of the intermediate routing portion 53 serves as a curved wall 52D formed by being curved toward the intermediate routing portion 53. The curved wall 52D is disposed in a region of the wire accommodating portion 52 where the main line 43 is accommodated. By providing the curved wall 52D, a width (interval in the lateral direction) of the wire accommodating portion 52 is widened. By accommodating the main line 43 into the wire accommodating portion 52 while curving the main line 43 toward the curved wall 52D (hereinafter, referred to as a contracted state), the entire main line 43 can be placed on the protector 50 (see FIG. 2). In the contracted state, the connector 60 is accommodated in the connector accommodating portion 55.

On the other hand, as shown in FIG. 5, a front part of the main line 43 is disposed to protrude from the protector 50 in a state where the main line 43 extends in the front-rear direction (hereinafter, referred to as an elongated state) in the region where the curved wall 52D is provided. In the elongated state, the connector 60 and the front part of the main line 43 protrude forward from the protector 50 and freely move, wherefore a connecting operation of the connector 60 and the mating connector can be performed (see FIG. 3). Further, since the main line 43 is fixed by the fixing portion 44, a tensile stress is not transferred to each wire 40 disposed behind the fixing portion 44 when the main line 43 is pulled forward.

As shown in FIGS. 4 and 5, parts near the second circuit board 24, out of the overlapping wires (two temperature detection lines 42), are disposed at positions near a front end part of the wire accommodating portion 52. In particular, the overlapping wires are introduced into the wire accommodating portion 52 from the intermediate routing portion 53 via the cut portion 52C disposed near the second circuit board 24, and are led out to the intermediate routing portion 53 from the wire accommodating portion 52 via the cut portion 52C provided immediately before the curved wall 52D after being routed to extend rearward in the wire accommodating portion 52. According to this configuration, the two temperature detection lines 42 can be routed in a space-saving manner on the protector 50 while avoiding the interference of the two temperature detection lines 42 and the first circuit board 21 disposed immediately behind the second circuit board 24.

### Cover, Ceiling Portion, Main Line Accommodating Portion

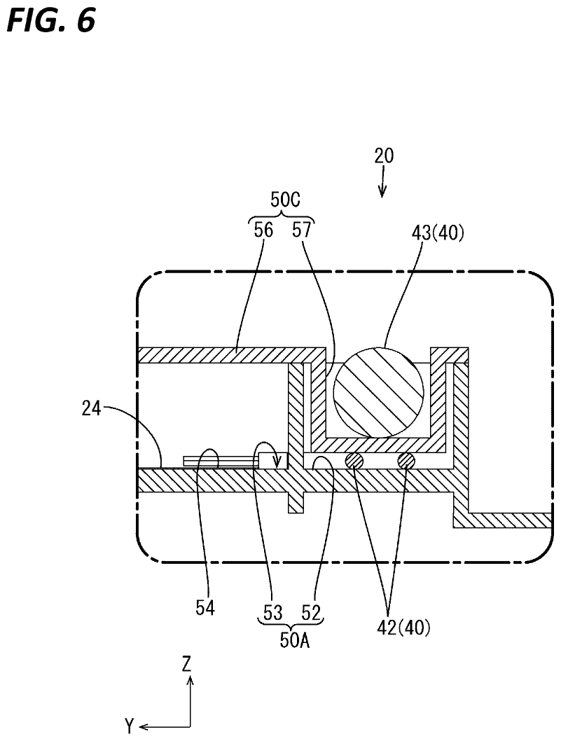

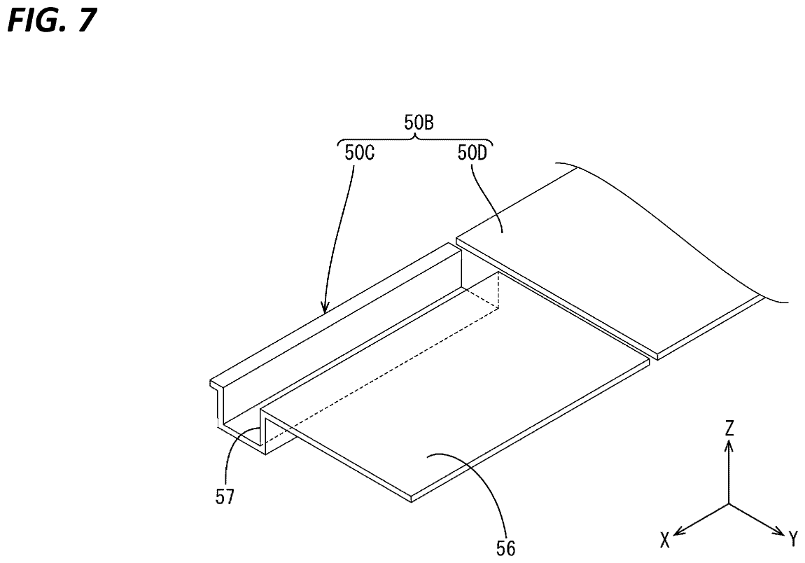

As shown in FIGS. 2 and 3, the cover 50B is configured to be able to close the wire accommodating portion 52 and the intermediate routing portion 53 (see FIGS. 4 and 5) of the protector body 50A from above. As shown in FIG. 7, the cover 50B is provided with a first cover 50C and a second cover 50D. The first cover 50C includes a ceiling plate portion 56 and the main line accommodating portion 57 recessed from the ceiling plate portion 56. The main line accommodating portion 57 is provided over the entire region of the first cover 50C in the front-rear direction and is open in the front-rear direction. As shown in FIG. 6, the ceiling plate portion 56 is disposed to face the placing surface 54 in the vertical direction. The main line accommodating portion 57 is disposed in the wire accommodating portion 52.

As shown in FIG. 7, the second cover 50D is plate-like. The second cover 50D is formed to have substantially the same thickness as the ceiling plate portion 56 of the first cover 50C. As shown in FIGS. 2 and 3, with the cover 50B mounted on the protector body 50A, the second cover 50D and the ceiling plate portion 56 of the first cover 50C are substantially continuously disposed in the front-rear direction. The first and second covers 50C, 50D can be separately mounted on the protector body 50A.

As shown in FIGS. 2 to 5, the first cover 50C closes the wire accommodating portion 52 disposed in a front end part of a left side of the protector body 50A and the intermediate routing portion 53. The second cover 50D closes the wire accommodating portion 52 and the intermediate routing portion 53 not closed by the first cover 50C. The main line accommodating portion 57 accommodates the front part of the main line 43. As shown in FIG. 6, the overlapping wires (two temperature detection lines 42) are accommodated in the wire accommodating portion 52 disposed below the main line accommodating portion 57. That is, the main line 43 and the overlapping wires are separated by the main line accommodating portion 57.

### Concerning Assembly of Wiring Module

The configuration of the wiring module 20 of this embodiment is as described above. An example of an assembly process of the wiring module 20 is described below.

First, the wires 40, the small metal pieces 15, the temperature measuring element 26 and the like are soldered to the respective circuit boards CB. The busbars 30, the circuit boards CB and the wires 40 are arranged with respect to the protector body 50A. The busbars 30 are accommodated into the busbar accommodating portions 51. The circuit boards are arranged in the intermediate routing portion 53. The busbars 30 and the small metal pieces 15 are connected by welding. The wires 40 are routed in the intermediate routing portion 53 and the wire accommodating portion 52. In the process of routing the wires 40, the main line 43 is formed by taping or the like.

Subsequently, the first cover 50C is mounted on the protector body 50A. The first cover 50C is arranged to sandwich the overlapping wires (two temperature detection lines 42) by the main line accommodating portion 57 and the wire accommodating portion 52 (see FIG. 6). At this time, the front part of the main line 43 is arranged outside the wire accommodating portion 52. After the first cover 50C is mounted on the protector body 50A, the front part of the main line 43 is accommodated into the main line accommodating portion 57. The main line disposed behind the main line accommodating portion 57 is accommodated in the wire accommodating portion 52.

Finally, the second cover 50D is mounted on the protector body 50A to close the wire accommodating portion 52 and the intermediate routing portion 53. In the above way, the assembly process of the wiring module 20 is completed.

### Concerning Effects of Main Line Accommodating Portion

In this embodiment, the overlapping wires (two temperature detection lines 42) and the main line 43 are partially disposed to overlap in the vertical direction. If the main line accommodating portion 57 is not provided, the overlapping wires and the main line 43 are disposed in the wire accommodating portion 52 and friction is possibly generated between the both. Since the wiring module 20 is applied to the vehicle 1, vibration is easily applied to the plurality of wires 40. Particularly, the vibration increases in the main line formed by integrating the plurality of wires 40, and the vibration of the main line 43 is possibly transmitted to the overlapping wires. Further, the main line 43 is connected to the connector 60 and it is assumed that a tensile stress is applied to the overlapping wires due to the friction of the main line 43 and the overlapping wires when this connector 60 is connected to the mating connector. Therefore, a load is applied to connected parts of the overlapping wires and the second circuit board 24 and these connected parts may be damaged.

In this embodiment, the main line 43 and the overlapping wires are separated not to contact each other by the main line accommodating portion 57 (see FIG. 6). Thus, friction is not generated between the main line 43 and the overlapping wires. Therefore, it can be suppressed that the connected parts of the overlapping wires and the second circuit board 24 are damaged due to the vibration of the main line 43 in an in-vehicle environment and a tensile stress of the main line 43 caused by the connecting operation of the connector 60 or the like.

### Functions and Effects of Embodiment

According to the embodiment, the following functions and effects are achieved.

The wiring module 20 according to the embodiment is to be attached to the plurality of power storage elements 11 and provided with the plurality of circuit boards CB, the plurality of wires 40 and the protector 50 for holding the plurality of circuit boards CB and the plurality of wires 40. The wire 40 is connected to the circuit board CB. At least some of the plurality of wires 40 are integrally bundled to constitute the main line 43. The protector 50 includes the plating surface 54, on which the circuit boards CB are placed, the wire accommodating portion 52 for accommodating the plurality of wires 40 and the main line accommodating portion 57 overlapped on the wire accommodating portion 52 in the first direction (vertical direction) orthogonal to the plating surface 54 for accommodating at least a part of the main line 43. The plurality of wires 40 include at least one overlapping wire (two temperature detection lines 42) to be disposed to overlap the main line 43 when viewed from the first direction, and the main line accommodating portion 57 separates the main line 43 and the at least one overlapping wire.

According to this configuration, since the main line accommodating portion 57 separates the main line 43 and the overlapping wire, friction is not generated between the main line 43 and the overlapping wire. Therefore, the damage of the connected part of the overlapping wire and the circuit board CB (second circuit board 24) can be suppressed.

Further, since the overlapping wire is disposed to overlap the main line 43 when viewed from the first direction, a routing region for the overlapping wire and the main line 43 can be reduced in a direction parallel to the plating surface 54. Therefore, the wiring module 20 can be reduced in size.

In this embodiment, the protector 50 includes the protector body 50 and the cover 50B to be overlapped on the protector body 50A in the first direction. The protector body 50A includes the plating surface 54 and the wire accommodating portion 52. The cover 50B includes the ceiling plate portion 56 facing the plating surface 54 in the first direction and the main line accommodating portion 57 recessed from the ceiling plate portion 56.

According to this configuration, the main line accommodating portion 57 can be simply configured. Further, the plating surface 54 can be covered by the ceiling plate portion 56.

### Other Embodiments

(1) Although the main line 43 is constituted by the plurality of wires 40 in the above embodiment, there is no limitation to this and a main line may be constituted by some of a plurality of wires.
(2) Although the overlapping wire is the temperature detection line 42 in the above embodiment, there is no limitation to this and an overlapping wire may be a wire different from the temperature detection line, e.g. a voltage detection line.
(3) Although the overlapping wire is included in the main line 43 in the above embodiment, there is no limitation to this and an overlapping wire may not be included in a main line.
(4) Although the protector body 50A and the cover 50B are separately provided in the above embodiment, there is no limitation to this and a protector body and a cover may be integrally provided, for example, by being coupled by a hinge.
(5) Although the wire accommodating portion 52 is formed with the curved wall 52D to enable the main line 43 to be accommodated in a curved state in the above embodiment, there is no limitation to this and a curved wall may not be formed.
(6) Although the first and second circuit boards 21, 24 are flexible boards in the above embodiment, there is no limitation to this and at least some of first and second circuit boards may be rigid boards.

### LIST OF REFERENCE NUMERALS

1: vehicle
2: power storage pack
3: PCU
4: wiring harness
10: power storage module
11: power storage element
15: small metal piece
20: wiring module
21 first circuit board
22: board body
22A: wire land
23: extending portion
24 second circuit board
25: board body
25A: wire land
26: temperature measuring element
30: busbar
30A: connection busbar
30B: output busbar
40: wire
41: voltage detection line
42: temperature detection line (overlapping wire)
43: main line
44: fixing portion
50: protector
50A: protector body
50B: cover
50C: first cover
50D: second cover
51: busbar accommodating portion
52: wire accommodating portion
52A: bottom wall
52B: side wall
52C: cut portion
52D: curved wall
53: intermediate routing portion
54: placing surface
55: connector accommodating portion
56: ceiling plate portion
57: main line accommodating portion
60: connector
CB: circuit board

1. A wiring module to be attached to a plurality of power storage elements, comprising:
a plurality of circuit boards;
a plurality of wires; and
a protector for holding the plurality of circuit boards and the plurality of wires,
the wire being connected to the circuit board,
at least some of the plurality of wires being integrally bundled to constitute a main line,
the protector including a placing surface, the circuit boards being placed on the placing surface, a wire accommodating portion for accommodating the plurality of wires and a main line accommodating portion overlapped on the wire accommodating portion in a first direction orthogonal to the placing surface for accommodating at least a part of the main line,
the plurality of wires including at least one overlapping wire to be disposed to overlap the main line when viewed from the first direction, and
the main line accommodating portion separating the main line and the at least one overlapping wire.

2. The wiring module of claim 1, wherein:
the protector includes a protector body and a cover to be overlapped on the protector body in the first direction,
the protector body includes the placing surface and the wire accommodating portion, and
the cover includes a ceiling plate portion facing the placing surface in the first direction and the main line accommodating portion recessed from the ceiling plate portion.
